(19) United States
(12) Patent Application Publication
(10) Pub. No.: US 2008/0137297 A1
(43) Pub. Date: Jun. 12, 2008

(54) FAN MODULE

(75) Inventors: Shao-Hua Hu, Taipei (TW); Chi-Chun Huang, Taipei (TW)

Correspondence Address: J C PATENTS, INC., 4 VENTURE, SUITE 250, IRVINE, CA, 92618, US

(73) Assignee: AMA PRECISION INC., Taipei (TW)

(21) Appl. No.: 11/942,431

(22) Filed: Nov. 19, 2007

(30) Foreign Application Priority Data
Dec. 7, 2006 (TW) 95145595

(51) Int. Cl. H05K 7/20

(52) U.S. Cl. 361/695

(57) ABSTRACT

A fan module including a fan and a light source set is provided. The fan includes a frame and a blade set. The frame has a accommodating space, an air inlet and an air outlet, and the air inlet and the air outlet are communicated with each other. The blade set is provided at the accommodating space. The light source set is provided at the frame as an independent module and has a circuit board and a plurality of light-emitting elements provided at the circuit board. Another fan module including a blade set base, a light source set, and a support is provided, wherein the light source set is provided at the blade set base. The light source set includes a circuit board and at least one light-emitting elements provided at the circuit board, and the circuit board is disposed between the blade set base and the support.

### CROSS-REFERENCE TO RELATED APPLICATION

This application claims the priority benefit of Taiwan application serial no. 95145595, filed on Dec. 7, 2006. The entirety of the above-mentioned patent application is hereby incorporated by reference herein and made a part of this specification.

### BACKGROUND OF THE INVENTION

1. Field of the Invention

The invention relates to a fan module and, more particularly, to a fan module with a light source set.

2. Description of Related Art

A fan is a needful element in electronic heat dissipation technology, and an electronic device can effectively decrease its interior working temperature via the convection effect between the active airflow generated by the fan and ambient environment. Additionally, modern fans further need to have unique models besides preferred heat dissipation efficiency, and then fans with light-emitting elements are developed.

FIG. 1A is an exploded diagram showing a conventional fan module, and FIG. 1B is a combined diagram showing the fan module in FIG. 1A. Please refer to FIGS. 1A and 1B at the same time, and a conventional fan module 100 mostly consists of a frame 110, a blade set 120 and a light-emitting element 130, wherein a casing 112 is provided at the frame 110 to prevent a user from being hurt because of contacting the rotary blade set 120, and the light-emitting element 130 is disposed in a through hole 112a of the casing 112. In this way, when the fan module is working, the light-emitting element 130 can generate light, and then the user gets preferred visual enjoyment. Additionally, the conventional technology further provides a protecting cover 114 at the casing 112 to prevent the light-emitting element 130 from being damaged by the collision of an external force.

Although the conventional fan module 100 has the light-emitting element 130, the light-emitting element 130 is disposed on the frame 110 directly, and then the user cannot choose a preferred fan according to usage requirements. Specifically, although there is a plurality of fan manufacturers on the market, only a few fan manufacturers manufacture the fan module 100 with the light-emitting element 130. Therefore, the user is limited in choosing the fan efficiency (The heat dissipation efficiency of the fan module 100 cannot satisfy an electronic device with high heat emitting power).

Additionally, the design of disposing the light-emitting element 130 at the frame 110 directly easily increases the maintenance cost of the fan module 100. For example, if the blade set is damaged and the light-emitting element can still work normally, the user cannot only replace the blade set but has to replace the whole fan module, which causes waste. Similarly, if the light-emitting element is damaged and the blade set can still works normally, the user still has to replace the whole fan module. In addition, in the conventional technology, since the light-emitting element is disposed in the casing, the material of the casing and the protecting cover must be a transparent material with higher cost, which causes the conventional fan module to have a higher product cost.

### BRIEF SUMMARY OF THE INVENTION

One objective of the invention is to provide a fan module whose light source set is suitable to cooperate with the fan chosen by a user.

Another objective of the invention is to provide a fan module to solve the problem that when a light source set or a blade set is damaged, a user cannot only replace the single component.

Another objective of the invention is to provide a fan module with a lower product cost.

To achieve the above objectives, the invention provides a fan module including a fan and a light source set. The fan includes a frame and a blade set. The frame have a accommodating space, an air inlet and an air outlet, wherein the air inlet and the air outlet are communicated with each other, and the blade set is provided at the accommodating space. Further, the light source set is provided at the frame, and includes a circuit board and a plurality of light-emitting elements provided at the circuit board.

In an embodiment of the invention, the above light-emitting elements are surface mount devices.

In an embodiment of the invention, the above light-emitting elements are light emitting diodes.

In an embodiment of the invention, the above fan module further includes a plurality of fasteners, and the frame has a plurality of first fixing holes, and the light source set provides a plurality of second fixing holes, wherein the fasteners are provided through the first fixing holes and the second fixing holes.

In an embodiment of the invention, the fan has a first power cord, and the light source set has a second power cord.

The invention further provides another fan module which includes a blade set base, a light source set provided at the blade set base, and a support. The light source set has a plurality of light-emitting elements and a circuit board, and the light-emitting elements are provided at the circuit board, and the circuit board is disposed between the blade set base and the support.

In an embodiment of the invention, the circuit board further includes a plurality of fifth fixing holes which are corresponding to the third fixing holes, and the fasteners are provided through the third fixing holes, the fourth fixing holes and the fifth fixing holes.

In an embodiment of the invention, the blade set base has a third power cord, and the light source set has a fourth power set.

A light source set of the invention is modularized, and therefore, a user can make the modularized light source set cooperate with a chosen fan, and does not need to appease a few specific manufacturers. Further, when the light source set or the blade set of the invention is damaged, only the light source set or the blade set needs to be replaced, thereby the maintenance cost of a fan module is decreased. In addition, since the light source set of the invention is modularized, the material of the frame is not limited to a transparent material with a higher cost, and, in other words, the fan module of the invention has a lower cost.

These and other features, aspects, and advantages of the present invention will become better understood with regard to the following description, appended claims, and accompanying drawings.

### BRIEF DESCRIPTION OF THE SEVERAL VIEWS OF THE DRAWINGS

FIG. 1A is an exploded diagram showing a conventional fan module.

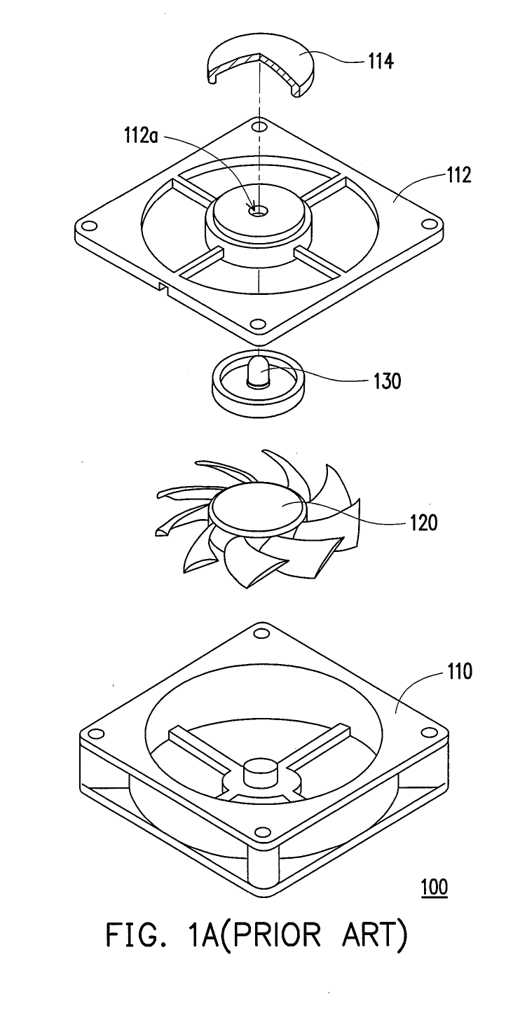

FIG. 1B is a combined diagram showing the fan module in FIG. 1A.

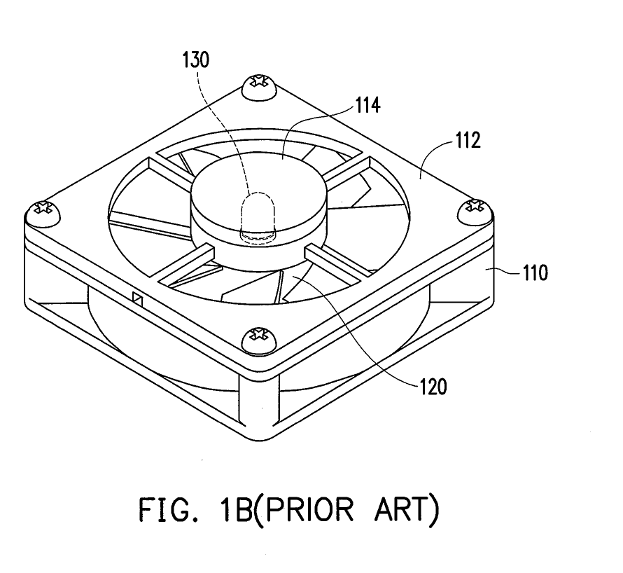

FIG. 2A is a three-dimensional schematic diagram showing a fan module in one preferred embodiment of the invention.

FIG. 2B is an exploded diagram showing the fan module in FIG. 2A.

FIG. 3 is a three-dimensional schematic diagram showing another fan module in one preferred embodiment of the invention.

FIG. 4A is a three-dimensional schematic diagram showing another fan module in one preferred embodiment of the invention.

FIG. 4B is an exploded diagram showing the fan module in FIG. 4A.

### DETAILED DESCRIPTION OF THE INVENTION

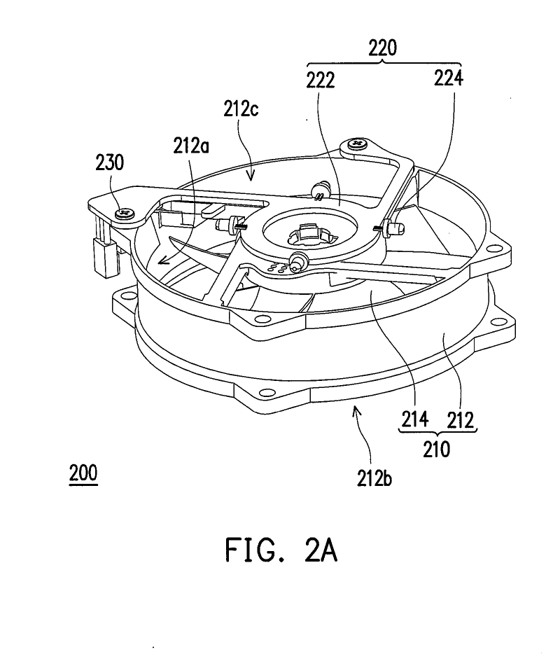

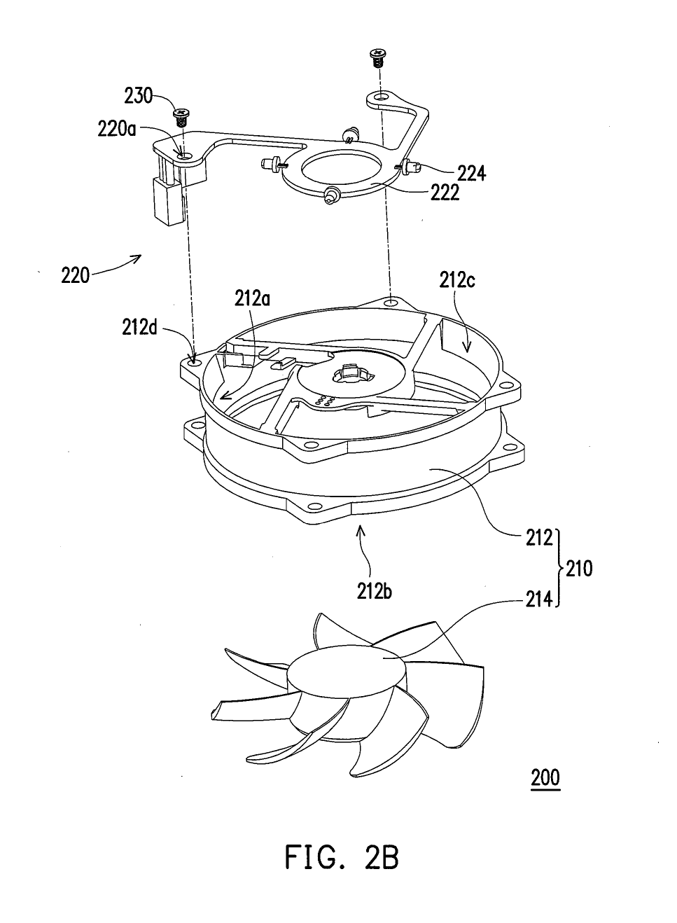

FIG. 2A is a three-dimensional schematic diagram showing a fan module in one preferred embodiment of the invention, and FIG. 2B is an exploded diagram showing the fan module in FIG. 2A. Please refer to FIG. 2A and FIG. 2B, and a fan module 200 in the embodiment includes a fan 210 and a light source set 220. In the embodiment, the fan 210 mostly includes a frame 212 and a blade set 214, and the frame 212 has a accommodating space 212a, an air inlet 212b, and an air outlet 212c. Wherein the blade set 214 is disposed in the accommodating space 212a, and the air inlet 212b and the air outlet 212c are communicated with each other. When the blade set 214 rotates, airflow is sucked from the air inlet 212b, and is exhausted from the air outlet 212c.

From the above, the light source set 220 in the embodiment is, for example, disposed on the frame 212 via a plurality of fasteners 230. For example, the frame 212 has a plurality of first fixing holes 212d, and the light source set 220 has a plurality of second fixing holes 220a, and the fasteners 230 such as screws are provided through the first fixing holes 212d and the second fixing holes 220a, thereby the light source set 220 can be assembled at the frame 212. Certainly, there is no limitation on the way to assemble the light source set 220 at the frame 212. That is, the light source set 220 can be assembled on the frame 212 in other way.

In the embodiment, the light source set 220 includes a circuit board 222 and a plurality of light-emitting elements 224 provided at the circuit board 222. Wherein the circuit board 222 in the embodiment can, for example, control the lightening frequency of the light-emitting elements 224, and then the light-emitting elements 224 such as surface mount devices or light emitting diodes can blink according to the lightening frequency set by the circuit board 222.

Since the light source set 220 is disposed on the frame 212 of the fan 210 as an independent module, the light source set 220 in the embodiment is suitable to cooperate with various fans. Specifically, the light source set 220 can cooperate with the fan 210 chosen by a user who does not need to appease a few specific manufacturers manufacturing fan modules with light-emitting elements. For example, when a user wants to make the fan module 200 be provided at an electronic device with high heat emitting power, the user can choose the fan 210 with preferred heat dissipation efficiency and assemble the light source set 220 on the fan 210, thereby the fan module 200 can have preferred heat dissipation efficiency and preferred visual effect simultaneously.

Additionally, since the fan 210 and the light source set 220 acts as independent modules, respectively, when the fan 210 or the light source set 220 is damaged, the user only needs to replace the damaged module instead of replacing the fan 210 and the light source set 220 at the same time. In other words, the fan module 200 in the embodiment has a lower maintenance cost. On the other hand, since the light source set 220 is disposed on the frame 212 of the fan 210 as an independent module, the material of the frame 212 is not limited to transparent material with a higher cost and has various choices, thereby the cost of the fan module 200 is decreased.

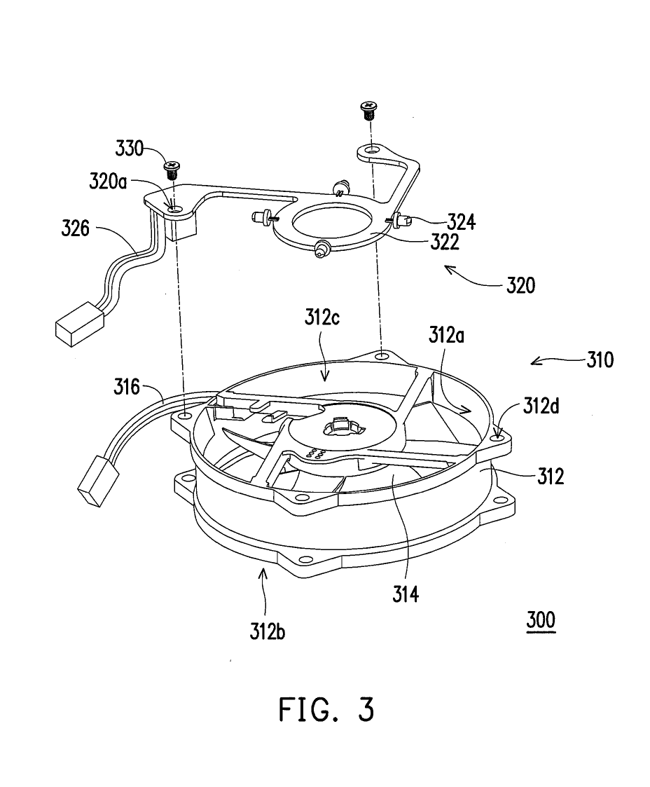

FIG. 3 is a three-dimensional schematic diagram showing another fan module in one preferred embodiment of the invention. Please refer to FIG. 3, and a fan module 300 in FIG. 3 is similar to the fan module 200 in the above embodiment, and the difference between them is that a fan 310 and a light source set 320 in the embodiment have individual power cords 316 and 326, respectively. In this way, the power cords 316 and 326 can be connected to different power interfaces (not shown), respectively, which decreases the quantity of the current on a single power cord, that is, the fan module 300 in the embodiment has a safer electrical characteristic.

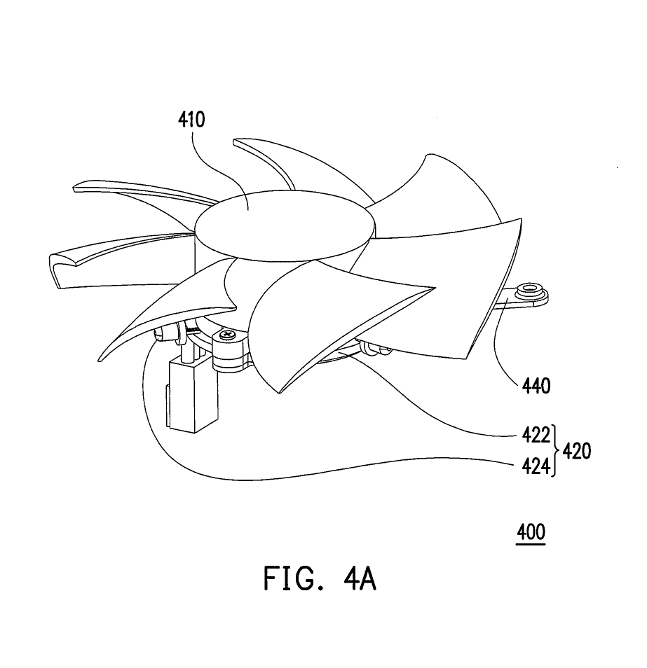

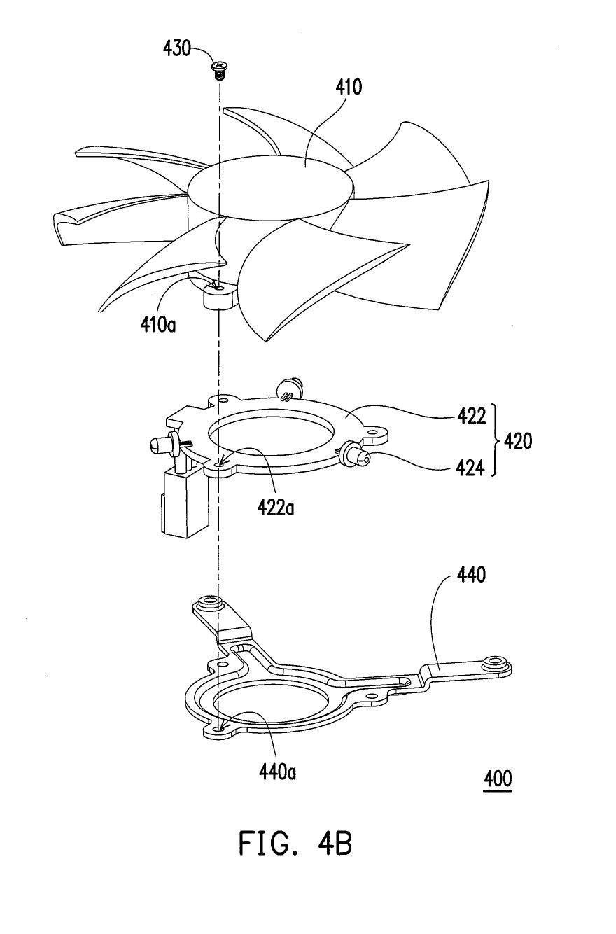

FIG. 4A is a three-dimensional schematic diagram showing another fan module in one preferred embodiment of the invention, and FIG. 4B is an exploded diagram showing the fan module in FIG. 4A. Please refer to FIGS. 4A and 4B, and a fan module 400 in the embodiment has no frame and is different from the fan module in the above embodiment as follows: a light source set 420 in the embodiment is assembled at a blade set base 410, and the light source set in the above embodiment is assembled on the frame. As shown in FIGS. 4A and 4B, the fan module 400 in the embodiment mostly includes a blade set base 410, a light source set 420 disposed on the blade set base 410, and a support 440. Wherein the light source set 420 has a circuit board 422 and a light-emitting elements 424 disposed on the circuit board 422, and the circuit board 422 can be disposed on the support 440 by locking, adhering or other appropriate ways. In the embodiment, the light source set 420 is fixed on the blade set base 410 by, for example, a plurality of fasteners 430. For example, the blade set base 410 can have a plurality of third fixing holes 410a, and the support 440 can have a plurality of fourth fixing holes 440a, and the fasteners 430 are provided through the third fixing holes 410a and the fourth fixing holes 440a, thereby the circuit board 422 can be held by the blade set base 410 and the support 440. In this way, the light source set 420 can be fixed on the blade set base 410.

Certainly, in other preferred embodiments, the circuit board 422 can further include a plurality of fifth fixing holes 422a which are corresponding to the third fixing holes 410a, and the fasteners 430 are provided through the third fixing holes 410a, the fourth fixing holes 440a and the fifth fixing holes 422a, thereby the circuit board 422 can be disposed on the support 440 more firmly.

To sum up, the light source set in the invention is modularized; therefore, the modularized light source set can cooperate with the fan chosen by users. Compared with the conventional technology, the invention has the following advantages:

first, since a light source set is disposed on a frame as an independent module, the light source set can cooperate with a fan chosen by a user who does not need to appease manufacturers;

second, since the fan and the light source set act as independent modules, respectively, when the fan or the light source set is damaged, the user only needs to replace the damaged module, thereby a fan module has a lower maintenance cost;

third, since the light source set is disposed on the frame of the fan as an independent module, the material of the frame is not limited to transparent material with a higher cost. In other words, the material of the frame has various choices, thereby the cost of the fan module is decreased; and

fourth, in the invention, the fan and the light source set have their own power cords, respectively, which decreases the quantity of the current on a single power cord, that is, the fan module in the invention has a safer electrical characteristic.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A fan module comprising:
a fan comprising:
a frame having a accommodating space, an air inlet and an air outlet, wherein the air inlet and the air outlet are communicated with each other; and
a blade set provided at the accommodating space; and
a light source set provided at the frame, wherein the light source set has at least one light-emitting element and a circuit board, and the light-emitting element is provided at the circuit board.

2. The fan module according to claim 1, wherein the light-emitting elements are surface mount device.

3. The fan module according to claim 1, wherein the light-emitting element is light emitting diode.

4. The fan module according to claim 1, further comprising a plurality of fasteners, the frame having a plurality of first fixing holes, and the light source set having a plurality of second fixing holes, wherein the fasteners are provided through the first fixing holes and the second fixing holes.

5. The fan module according to claim 1, wherein the fan has a first power cord, and the light source set has a second power cord.

6. A fan module comprising:
a blade set base;
a light source set provided at the blade set base, wherein the light source set has at least one light-emitting element and a circuit board, and the light-emitting element is provided at the circuit board; and
a support, wherein the circuit board are provided between the blade set base and the support.

7. The fan module according to claim 6, wherein the light-emitting element is surface mount device.

8. The fan module according to claim 6, wherein the light-emitting element is light emitting diode.

9. The fan module according to claim 6, further comprising a plurality of fasteners, the blade set base having a plurality of third fixing holes, and the support having a plurality of fourth fixing holes corresponding to the third fixing holes, wherein the fasteners are provided through the third fixing holes and the fourth fixing holes, and the circuit board is held between the blade set base and the support.

10. The fan module according to claim 9, wherein the circuit board further comprises a plurality of fifth fixing holes which are corresponding to the third fixing holes, and the fasteners are provided through the third fixing holes, the fourth fixing holes and the fifth fixing holes.

11. The fan module according to claim 6, wherein the blade set base has a third power cord, and the light source set has a fourth power cord.
